(19) United States
(12) Patent Application Publication
(10) Pub. No.: US 2023/0163074 A1
(43) Pub. Date: May 25, 2023

(54) CHIP PACKAGING STRUCTURE AND MANUFACTURING METHOD THEREOF

(71) Applicant: Unimicron Technology Corp., Taoyuan City (TW)

(72) Inventors: Tzyy-Jang Tseng, Taoyuan City (TW); John Hon-Shing Lau, Taoyuan City (TW); Pu-Ju Lin, Hsinchu City (TW); Cheng-Ta Ko, Taipei City (TW)

(73) Assignee: Unimicron Technology Corp., Taoyuan City (TW)

(21) Appl. No.: 17/569,509

(22) Filed: Jan. 6, 2022

(30) Foreign Application Priority Data
Nov. 19, 2021 (TW) 110143145

(51) Int. Cl. H01L 23/532; H01L 23/495; H01L 23/538

(52) U.S. Cl. CPC H01L 23/5329; H01L 23/53238; H01L 23/49503; H01L 23/5389

(57) ABSTRACT

A chip packaging structure and a manufacturing method thereof are provided. The chip packaging structure includes a substrate, at least one first chip, an adhesive material, a redistribution circuit structure, and multiple second chips. The substrate has a first surface, a second surface opposite to the first surface, and at least one cavity. The at least one first chip is disposed in the at least one cavity. The adhesive material is disposed in the at least one cavity and located between the substrate and the at least one first chip. The redistribution circuit structure is disposed on the first surface of the substrate, and is electrically connected to the at least one first chip. The second chips are disposed on the redistribution circuit structure, and are electrically connected to the redistribution circuit structure.

### CROSS-REFERENCE TO RELATED APPLICATION

This application claims the priority benefit of Taiwan application serial no. 110143145, filed on Nov. 19, 2021. The entirety of the above-mentioned patent application is hereby incorporated by reference herein and made a part of this specification.

### BACKGROUND

### Technical Field

The disclosure relates to a packaging structure, and more particularly, to a chip packaging structure and a manufacturing method thereof.

### Description of Related Art

At present, in the mini LED panel or micro LED panel, mini light emitting diodes or micro light emitting diodes are usually disposed on a front surface of a printed circuit board (or an IC carrier board), and a packaged driver IC is disposed on a back surface or side of the printed circuit board (or the IC carrier board). As a result, the thickness of the entire panel will be increased.

In addition, the printed circuit board (or the IC carrier board) often has issues of warpage and poor flatness of the copper surface. Therefore, it is not conducive to the massive transfer of mini light emitting diodes, and increases the possibility of assembly failure, thereby affecting the yield of the finished product.

### SUMMARY

The disclosure provides a chip packaging structure and a manufacturing method thereof, which has a technical effect of reducing an entire thickness or may effectively improve a yield of a product.

A chip packaging structure in the disclosure includes a substrate, at least one first chip, an adhesive material, a redistribution circuit structure, and multiple second chips. The substrate has a first surface, a second surface opposite to the first surface, and at least one cavity. The at least one first chip is disposed in the at least one cavity. The adhesive material is disposed in the at least one cavity and located between the substrate and the at least one first chip. The redistribution circuit structure is disposed on the first surface of the substrate, and is electrically connected to the at least one first chip. The second chips are disposed on the redistribution circuit structure, and are electrically connected to the redistribution circuit structure.

In an embodiment of the disclosure, the substrate is a glass substrate or a silicon substrate.

In an embodiment of the disclosure, the at least one first chip is a bare die.

In an embodiment of the disclosure, the second chips include a bare die and/or a packaged chip.

In an embodiment of the disclosure, the redistribution circuit structure includes a first dielectric layer, a first patterned circuit layer, a first through hole, a second dielectric layer, a second patterned circuit layer, and a second through hole. The first dielectric layer is disposed on the first surface of the substrate. The first patterned circuit layer is disposed on the first dielectric layer. The first through hole penetrates the first dielectric layer, and the first through hole is electrically connected to the first patterned circuit layer and the at least one first chip. The second dielectric layer is disposed on the first patterned circuit layer. The second patterned circuit layer is disposed on the second dielectric layer. The second through hole penetrates the second dielectric layer, and the second through hole is electrically connected to the second patterned circuit layer and the first patterned circuit layer.

In an embodiment of the disclosure, an active surface of the at least one first chip is flush with the first surface of the substrate.

In an embodiment of the disclosure, the chip packaging structure further includes a connecting member. The connecting member is disposed on the redistribution circuit structure, and the second chips are electrically connected to the redistribution circuit structure through the connecting member.

In an embodiment of the disclosure, the connecting member includes a contact pad and a solder joint. The contact pad may be connected to the redistribution circuit structure. The solder joint is disposed on the contact pad, and the solder joint may be electrically connected to the contact pad.

A manufacturing method of a chip packaging structure in the disclosure includes the following steps. First, a substrate is provided. The substrate has a first surface, a second surface opposite to the first surface, and at least one cavity. Then, at least one first chip and an adhesive material are disposed in the at least one cavity, so that the adhesive material is located between the substrate and the at least one first chip. Next, a redistribution circuit structure is formed on the first surface of the substrate to be electrically connected to the at least one first chip. Afterwards, multiple second chips are disposed on the redistribution circuit structure to be electrically connected to the redistribution circuit structure.

In an embodiment of the disclosure, forming the redistribution circuit structure on the first surface of the substrate includes the following steps. First, a first dielectric layer is formed on the first surface of the substrate by a planarization process. Then, a first patterned circuit layer is formed on the first dielectric layer, and a first through hole is formed in the first dielectric layer. The first through hole penetrates the first dielectric layer, and the first through hole is electrically connected to the first patterned circuit layer and the at least one first chip. Next, a second dielectric layer is formed on the first patterned circuit layer. Afterwards, a second patterned circuit layer is formed on the second dielectric layer, and a second through hole is formed in the second dielectric layer. The second through hole penetrates the second dielectric layer, and is electrically connected to the second patterned circuit layer and the first patterned circuit layer.

In an embodiment of the disclosure, the manufacturing method of the chip packaging structure further includes the following step. A connecting member is formed on the redistribution circuit structure, so that the second chips are electrically connected to the redistribution circuit structure through the connecting member.

Based on the above, in the chip packaging structure according to an embodiment of the disclosure, by embedding the first chip in the substrate, the thickness of the entire chip packaging structure may be reduced. Furthermore, since the first chip in this embodiment may be embedded in the substrate and is the bare die, the issue of warpage of the substrate caused by the use of the packaged chip may be avoided, and the rigidity and the flatness of the substrate may also be maintained, which may effectively reduce the possibility of assembly failure caused by the warpage of the substrate, thereby improving the yield of the product.

In order for the aforementioned features and advantages of the disclosure to be more comprehensible, embodiments accompanied with drawings are described in detail below.

### BRIEF DESCRIPTION OF THE DRAWINGS

FIG. 1 is a flowchart of a manufacturing method of a chip packaging structure according to an embodiment of the disclosure.

FIGS. 2A to 2D are schematic cross-sectional views of a manufacturing method of a chip packaging structure according to an embodiment of the disclosure.

### DETAILED DESCRIPTION OF DISCLOSED EMBODIMENTS

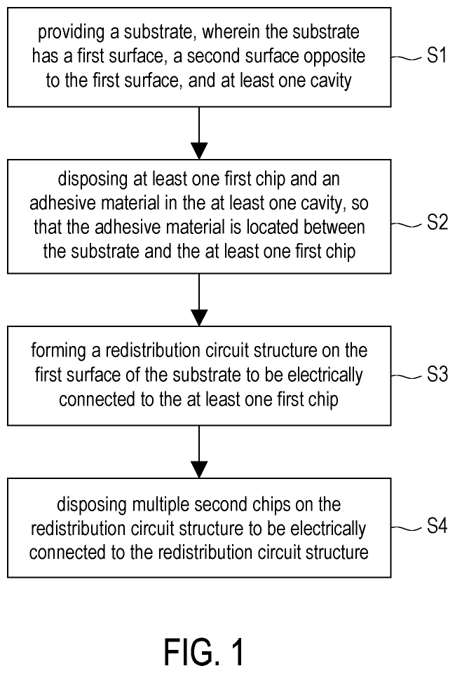

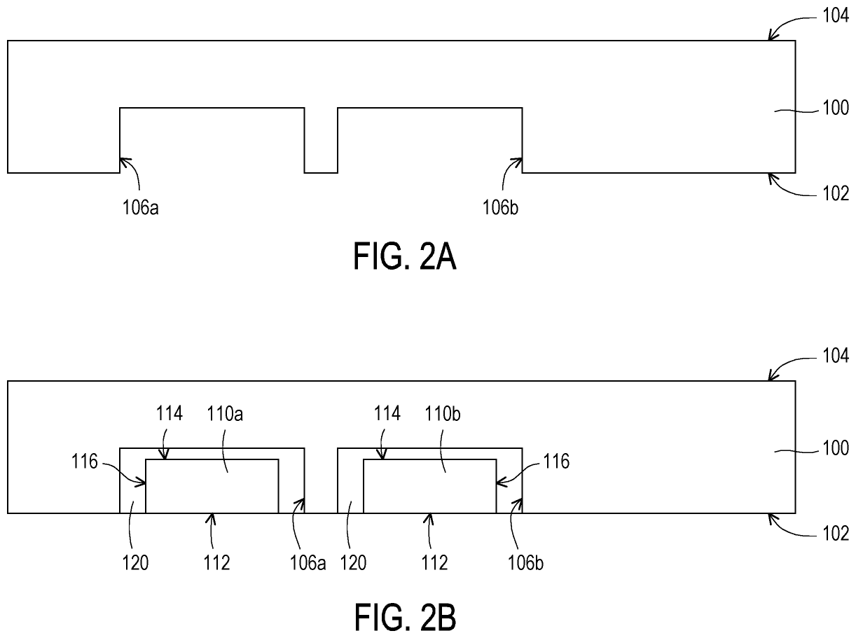

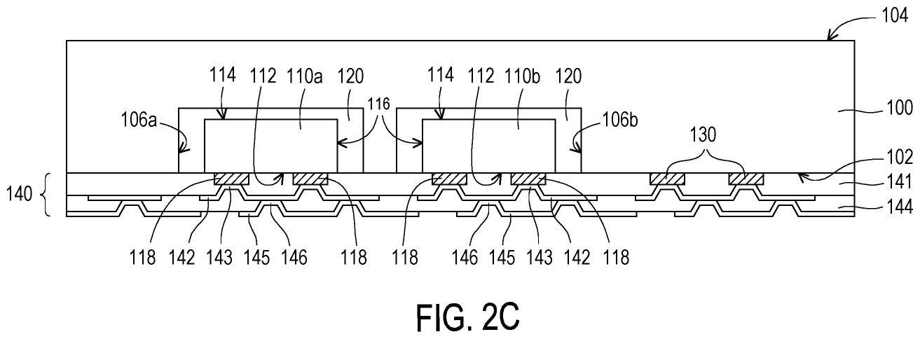

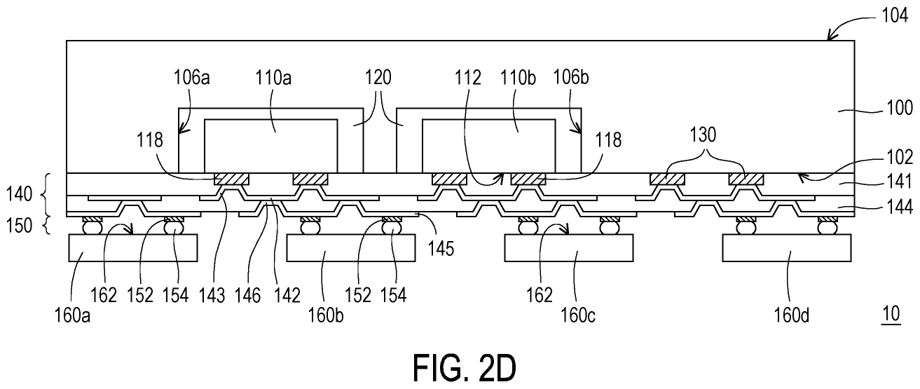

FIG. 1 is a flowchart of a manufacturing method of a chip packaging structure according to an embodiment of the disclosure. FIGS. 2A to 2D are schematic cross-sectional views of a manufacturing method of a chip packaging structure according to an embodiment of the disclosure.

A manufacturing method of a chip packaging structure 10 in this embodiment may include the following steps.

First, referring to FIGS. 1 and 2A, a step S1 is performed. A substrate 100 is provided. The substrate 100 has a first surface 102, a second surface 104 opposite to the first surface 102, and at least one cavity 106a and 106b (two cavities are exemplarily shown in FIG. 2A, but are not limited thereto; that is to say, the number of cavities may be adjusted according to requirements). In this embodiment, since the substrate 100 may be a rigid substrate, and the first surface 102 of the substrate 100 may have extremely excellent flatness, it is helpful to manufacture fine lines in a subsequent manufacturing process. Here, the substrate 100 may be, for example, a glass substrate, a ceramic substrate, a silicon substrate, or other suitable substrates, but is not limited thereto.

In this embodiment, the cavities 106a and 106b are recessed from the first surface 102 of the substrate 100 toward the second surface 104, and the cavities 106a and 106b do not penetrate the substrate 100. From the cross-sectional view, the cavities 106a and 106b may be U-shaped openings, but the disclosure is not limited thereto. In this embodiment, the cavities 106a and 106b may be formed by, for example, wet etching or other suitable processes.

Next, referring to FIGS. 1 and 2B, a step S2 is performed. At least one first chip 110a and 110b and an adhesive material 120 are disposed in the at least one cavity 106a and 106b, so that the adhesive material 120 is located between the substrate 100 and the at least one first chip 110a and 110b. In this embodiment, each of the first chips 110a and 110b may be correspondingly disposed in each of the cavities 106a and 106b. For example, as shown in FIG. 2B, the first chip 110a may be disposed in the cavity 106a, and the first chip 110b may be disposed in the cavity 106b. The first chips 110a and 110b have an active surface 112, a back surface 114 opposite to the active surface 112, and a surrounding surface 116 connecting the active surface 112 and the back surface 114. The active surface 112 faces and is adjacent to the first surface 102. In this embodiment, the active surface 112 of the first chips 110a and 110b may be flush with the first surface 102 of the substrate 100, but the disclosure is not limited thereto. The first chips 110a and 110b may be bare dies, and functions of the first chip 110a and the first chip 110b may be the same or different. For example, in this embodiment, the first chip 110a and the first chip 110b may be, for example, a source drive IC, a gate driver IC, or a chip with other functions. In other embodiments, the first chip 110a may be, for example, a passive device, and the first chip 110b may be, for example, a surface mount device (SMD). The disclosure is not limited thereto.

The adhesive material 120 may be disposed in a gap between the substrate 100 and the back surface 114 of the first chips 110a and 110b, and may be disposed in a gap between the substrate 100 and the surrounding surface 116 of the first chips 110a and 110b. That is, the adhesive material 120 may cover the active surface 112 and the surrounding surface 116 of the first chips 110a and 110b, thereby helping to fix the first chips 110a and 110b in the cavities 106a and 106b. In this embodiment, a method of disposing the first chips 110a and 110b in the cavities 106a and 106b may be, for example, to first fill the adhesive material 120 in the cavities 106a and 106b, and then put the first chips 110a and 110b into the cavities 106a and 106b. The adhesive material 120 may be, for example, a resin, epoxy, or other suitable materials, but is not limited thereto.

In this embodiment, by embedding the first chips 110a and 110b in the substrate 100, a thickness of the entire chip packaging structure 10 (as shown in FIG. 2D) in this embodiment may be reduced. Furthermore, compared with a conventional chip packaging structure in which a packaged chip having a dissimilar material (i.e., an encapsulation gel of a non-embedded chip packaging structure) is disposed on the substrate, causing the substrate to warp, since the first chips 110a and 110b of the chip packaging structure 10 in this embodiment may be embedded in the substrate 100 and are bare dies (that is, not the packaged chips), an issue of warpage of the substrate 100 caused by the use of the dissimilar material may be avoided, and rigidity and flatness of the substrate 100 may be maintained, thereby improving the yield of the product. In addition, since the substrate 100 has the rigidity and the excellent flatness, the issue of warpage of the substrate 100 may also be effectively reduced.

Next, referring to FIGS. 1 and 2C, a step S3 is performed. A redistribution circuit structure 140 is formed on the first surface 102 of the substrate 100 to be electrically connected to the at least one first chip 110a and 110b. In this embodiment, steps of forming the redistribution circuit structure 140 on the first surface 102 of the substrate 100 may include, but are not limited to, the following steps.

First, a pad 118 is formed on the active surface 112 of the first chips 110a and 110b, and a pad 130 is formed on the first surface 102 of the substrate 100 at the same time. The pad 118 and the pad 130 can be regarded as patterned circuit layers. Next, a first dielectric layer 141 is formed on the first surface 102 of the substrate 100 by a planarization process (for example, a lamination process) to cover the first surface 102 of the substrate 100 and the active surface 112 of the first chips 110a and 110b. In this embodiment, the first dielectric layer 141 may be regarded as a planar layer. For example, in some embodiments, when the adhesive material 120 does not fill a gap between the substrate 100 and the first chips 110a and 110b, the first dielectric layer 141 may be used to fill the gap and provide a flattened surface, so as to facilitate subsequent formation of the first patterned circuit layer 142. A material of the first dielectric layer 141 may be, for example, a dielectric material with a flattening effect, such as Ajinomoto build-up film (ABF), polyimide, or other suitable materials, but is not limited thereto. A thickness of the first dielectric layer 141 in this embodiment may be, for example, between 10 μm and 40 μm, but is not limited thereto. Specifically, the thickness of the first dielectric layer 141 needs to match with a thickness of the patterned circuit layer (that is, the pads 118 and 130). Here, a thickness of the pads 118 and 130 in this embodiment may be, for example, between 4 μm and 8 μm. Therefore, when the thickness of the first dielectric layer 141 is less than 10 μm, the manufacturing difficulty is high, and the flexibility of the high-frequency impedance matching design is small. Furthermore, since a coefficient of thermal expansion (CTE) of the first dielectric material is relatively large, when the thickness of the first dielectric layer 141 is greater than 40 μm, it is easy to cause the warpage of the entire structure to increase.

Next, the first patterned circuit layer 142 is formed on the first dielectric layer 141, and a first through hole 143 is formed in the first dielectric layer 141. Specifically, the first through hole 143 may penetrate the first dielectric layer 141 to be electrically connected to the first patterned circuit layer 142 and the pad 118 of the first chips 110a and 110b. Here, materials of the first patterned circuit layer 142 and the first through hole 143 may be, for example, copper or other conductive materials.

Then, a second dielectric layer 144 is formed on the first patterned circuit layer 142. The second dielectric layer 144 may be formed on the first patterned circuit layer 142 by, for example, the lamination process, a liquid coating process, or other suitable processes, so as to cover the first dielectric layer 141, the first patterned circuit layer 142, and the first through hole 143. In this embodiment, a material of the second dielectric layer 144 may be, for example, a photosensitive dielectric material, a non-photosensitive dielectric material, or other suitable materials. In addition, the material of the second dielectric layer 144 may also be the same as or different from the material of the first dielectric layer 141, and the disclosure is not limited thereto. A thickness of the first patterned circuit layer 142 in this embodiment may be, for example, between 2 μm and 6 μm, and a thickness of the second dielectric layer 144 may be, for example, less than 10 μm, but are not limited thereto. When the thickness of the second dielectric layer 144 is less than 10 μm, the entire thickness may be thinner, having relatively low residual stress. As a result, the occurrence of warpage may be reduced.

Afterwards, a second patterned circuit layer 145 is formed on the second dielectric layer 144, and a second through hole 146 is formed in the second dielectric layer 144. The second through hole 146 penetrates the second dielectric layer 144, and are electrically connected to the second patterned circuit layer 145 and the first patterned circuit layer 142. So far, the redistribution circuit structure 140 in this embodiment has been manufactured.

In this embodiment, the redistribution circuit structure 140 is exemplarily shown as an alternate laminated structure of a two-layer dielectric layer (the first dielectric layer 141 and the second dielectric layer 144) and a three-layer patterned circuit layer (the patterned circuit layer, the first patterned circuit layer 142, and the second patterned circuit layer 145), but the disclosure is not limited thereto. In some embodiments, those skilled in the art may increase the number of layers of the redistribution circuit structure 140 according to actual requirements.

In addition, in this embodiment, the substrate 100 has the rigidity and the excellent flatness. Therefore, each of the circuits (i.e., the first patterned circuit layer 142, the second patterned circuit layer 145, the first through hole 143, and the second through hole 146) in the redistribution circuit structure 140 disposed on the substrate 100 may be the fine line.

Next, referring to both FIGS. 1 and 2D, a step S4 is performed. Multiple second chips 160a, 160b, 160c, and 160d are disposed on the redistribution circuit structure 140 to be electrically connected to the redistribution circuit structure 140. In this embodiment, steps of disposing the second chips 160a, 160b, 160c, and 160d on the redistribution circuit structure 140 may include, but are not limited to, the following steps, for example.

First, a connecting member 150 is formed on the redistribution circuit structure 140. In this embodiment, the connecting member 150 may include a contact pad 152 and a solder joint 154, but is not limited thereto. In other embodiments, the connecting member 150 may be, for example, a conductive pillar (not shown) or other suitable conductive connectors (not shown). Specifically, as shown in FIG. 2D, the contact pad 152 in this embodiment may be connected to the second patterned circuit layer 145 in the redistribution circuit structure 140. The solder joint 154 may be disposed on the contact pad 152, and the solder joint 154 may be electrically connected to the contact pad 152. Here, a material of the contact pad 152 may be, for example, copper or other suitable metal conductive materials, and a material of the solder joint 154 may be, for example, tin, silver, copper, gold, an alloy thereof, or other suitable metal conductive materials. However, the disclosure is not limited thereto.

Next, the second chips 160a, 160b, 160c, and 160d are disposed on the connecting member 150, so that the second chips 160a, 160b, 160c, and 160d may be electrically connected to the redistribution circuit structure 140 through the connecting member 150. So far, the chip packaging structure 10 in this embodiment has been manufactured.

In this embodiment, an active surface 162 of the second chips 160a, 160b, 160c, and 160d faces the connecting member 150, and is electrically connected to the corresponding connecting member 150. The second chips 160a, 160b, 160c, and 160d may be the bare dies and/or the packaged chips, and the disclosure is not limited thereto. In addition, functions of the second chip 160a, the second chip 160b, the second chip 160c, and the second chip 160d may be the same or different. For example, in this embodiment, the second chips 160a, 160b, 160c, and 160d may be, for example, mini light emitting diodes, surface mount devices (SMD), memory devices, or chips with other functions, and the disclosure is not limited thereto.

In brief, the chip packaging structure 10 in this embodiment includes the substrate 100, the at least one first chip 110a and 110b, an adhesive material 120, the redistribution circuit structure 140, and the second chips 160a, 160b, 160c, and 160d. The substrate 100 has the first surface 102, the second surface 104 opposite to the first surface 102, and the at least one cavity 106a and 106b. The at least one first chip 110a and 110b is disposed in the cavities 106a and 106b. The adhesive material 120 is disposed in the at least one cavity 106a and 106b, and is located between the substrate 100 and the at least one first chip 110a and 110b. The redistribution circuit structure 140 is disposed on the first surface 102 of the substrate 100, and is electrically connected to the at least one first chip 110a and 110b. The second chips 160a, 160b, 160c, and 160d are disposed on the redistribution circuit structure 140, and are electrically connected to the redistribution circuit structure 140.

Based on the above, in the chip packaging structure according to an embodiment of the disclosure, by embedding the first chips in the substrate, the thickness of the entire chip packaging structure in this embodiment may be reduced. Furthermore, compared with the conventional chip packaging structure in which the packaged chip having the dissimilar material is disposed on the substrate, causing the substrate to warp, since the first chips in this embodiment may be embedded in the substrate and are the bare dies, the issue of warpage of the substrate caused by the use of the dissimilar material may be avoided, and the rigidity and the flatness of the substrate may also be maintained, thereby improving the yield of the product.

Although the disclosure has been described with reference to the above embodiments, it will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A chip packaging structure, comprising:
a substrate having a first surface, a second surface opposite to the first surface, and at least one cavity;
at least one first chip disposed in the at least one cavity;
an adhesive material disposed in the at least one cavity and located between the substrate and the at least one first chip;
a redistribution circuit structure disposed on the first surface of the substrate and electrically connected to the at least one first chip; and
a plurality of second chips disposed on the redistribution circuit structure and electrically connected to the redistribution circuit structure.

2. The chip packaging structure according to claim 1, wherein the substrate is a glass substrate or a silicon substrate.

3. The chip packaging structure according to claim 1, wherein the at least one first chip is a bare die.

4. The chip packaging structure according to claim 1, wherein the plurality of second chips includes a bare die and/or a packaged chip.

5. The chip packaging structure according to claim 1, wherein the redistribution circuit structure comprises:
a first dielectric layer disposed on the first surface of the substrate;
a first patterned circuit layer disposed on the first dielectric layer;
a first through hole penetrating the first dielectric layer and electrically connected to the first patterned circuit layer and the at least one first chip;
a second dielectric layer disposed on the first patterned circuit layer;
a second patterned circuit layer disposed on the second dielectric layer; and
a second through hole penetrating the second dielectric layer and electrically connected to the second patterned circuit layer and the first patterned circuit layer.

6. The chip packaging structure according to claim 1, wherein the at least one first chip has an active surface, a back surface opposite to the active surface, and a pad, the pad is disposed on the active surface, and the at least one first chip is electrically connected to the redistribution circuit structure through the pad.

7. The chip packaging structure according to claim 6, wherein the active surface of the at least one first chip is flush with the first surface of the substrate.

8. The chip packaging structure according to claim 1, further comprising:
a connecting member disposed on the redistribution circuit structure, wherein the plurality of second chips is electrically connected to the redistribution circuit structure through the connecting member.

9. The chip packaging structure according to claim 8, wherein the connecting member comprises:
a contact pad connected to the redistribution circuit structure; and
a solder joint disposed on the contact pad and electrically connected to the contact pad.

10. A manufacturing method of a chip packaging structure, comprising:
providing a substrate, wherein the substrate has a first surface, a second surface opposite to the first surface, and at least one cavity;
disposing at least one first chip and an adhesive material in the at least one cavity, so that the adhesive material is located between the substrate and the at least one first chip;
forming a redistribution circuit structure on the first surface of the substrate to be electrically connected to the at least one first chip; and
disposing a plurality of second chips on the redistribution circuit structure to be electrically connected to the redistribution circuit structure.

11. The manufacturing method of the chip packaging structure according to claim 10, wherein forming the redistribution circuit structure on the first surface of the substrate comprises:
forming a first dielectric layer on the first surface of the substrate by a planarization process;
forming a first patterned circuit layer on the first dielectric layer, and forming a first through hole in the first dielectric layer, wherein the first through hole penetrates the first dielectric layer, and is electrically connected to the first patterned circuit layer and the at least one first chip;
forming a second dielectric layer on the first patterned circuit layer; and
forming a second patterned circuit layer on the second dielectric layer, and forming a second through hole in the second dielectric layer, wherein the second through hole penetrates the second dielectric layer, and is electrically connected to the second patterned circuit layer and the first patterned circuit layer.

12. The manufacturing method of the chip packaging structure according to claim 10, further comprising:
forming a connecting member on the redistribution circuit structure, so that the plurality of second chips is electrically connected to the redistribution circuit structure through the connecting member.
